(19) United States
(12) Patent Application Publication
(10) Pub. No.: US 2025/0318043 A1
(43) Pub. Date: Oct. 9, 2025

(54) CIRCUIT BOARD STRUCTURE

(71) Applicant: ASUSTeK COMPUTER INC., Taipei City (TW)

(72) Inventors: Hank Lin, Taipei City (TW); Bin-Chyi Tseng, Taipei City (TW); Tsung-Chieh Yen, Taipei City (TW)

(73) Assignee: ASUSTeK COMPUTER INC., Taipei City (TW)

(21) Appl. No.: 19/082,208

(22) Filed: Mar. 18, 2025

(30) Foreign Application Priority Data
Apr. 3, 2024 (TW) 113112664

(51) Int. Cl. H05K 1/02; H05K 1/11; H05K 1/18

(52) U.S. Cl. CPC H05K 1/0228; H05K 1/113; H05K 1/115; H05K 1/181; H05K 2201/09618; H05K 2201/09636

(57) ABSTRACT

Disclosed is a circuit board structure including multiple circuit layers, a first via hole signal transmission region group and a second via hole signal transmission region group. The circuit layers include a first pad group and a second pad group located on different layers. The first via hole signal transmission region group is connected to the first pad group and conducted to ones of the circuit layers. Two adjacent via hole signal transmission regions in the first via hole signal transmission region group have different lengths. The second via hole signal transmission region group is conducted to the ones of the circuit layers and is conducted to the first via hole signal transmission region group. The second via hole signal transmission region group is connected to the second pad group. Two adjacent via hole signal transmission regions in the second via hole signal transmission region group have different lengths.

### CROSS-REFERENCE TO RELATED APPLICATION

This application claims the priority benefit of Taiwan application serial no. 113112664, filed on Apr. 3, 2024. The entirety of the above-mentioned patent application is hereby incorporated by reference herein and made a part of this specification.

### BACKGROUND

### Technical Field

The present disclosure is related to a circuit board structure.

### Description of Related Art

Two components on different planes of a circuit board may be electrically connected to a trace through a segment (via hole signal transmission region) in a via hole for transmitting signals. In current technologies, the traces connected in two adjacent via hole signal transmission regions are on the same layer, which results in the same length of the two adjacent via hole signal transmission regions. Consequently, mutual coupling is likely to occur and crosstalk is increased accordingly, and therefore signal performance is affected.

### SUMMARY

The present disclosure provides a circuit board structure that may have an improved signal performance.

In the present disclosure, a circuit board structure includes a plurality of circuit layers, a first via hole signal transmission region group and a second via hole signal transmission region group. The plurality of circuit layers are stacked at intervals and include a first pad group and a second pad group located on different layers. The first via hole signal transmission region group is connected to the first pad group and conducted to ones of the plurality of circuit layers. Two adjacent via hole signal transmission regions in the first via hole signal transmission region group have different lengths. The second via hole signal transmission region group is conducted to the ones of the plurality of circuit layers and is conducted to the first via hole signal transmission region group. The second via hole signal transmission region group is connected to the second pad group. Two adjacent via hole signal transmission regions in the second via hole signal transmission region group have different lengths.

Based on the above, the circuit board structure of the present disclosure allows the first pad group and the second pad group to be electrically connected through the first via hole signal transmission region group and the second via hole signal transmission region group. Two adjacent via hole signal transmission regions in the first via hole signal transmission region group have different lengths, and two adjacent via hole signal transmission regions in the second via hole signal transmission region group have different lengths. Such design makes it possible to reduce the probability that two adjacent via hole signal transmission regions in the first via hole signal transmission region group and the second via hole signal transmission region group are coupled to each other, thereby reducing crosstalk and improving signal performance.

### BRIEF DESCRIPTION OF THE DRAWINGS

FIG. 1 is a schematic diagram of a circuit board structure according to an embodiment of the present disclosure.

FIG. 2 is a schematic diagram of a circuit board structure according to another embodiment of the present disclosure.

### DESCRIPTION OF THE EMBODIMENTS

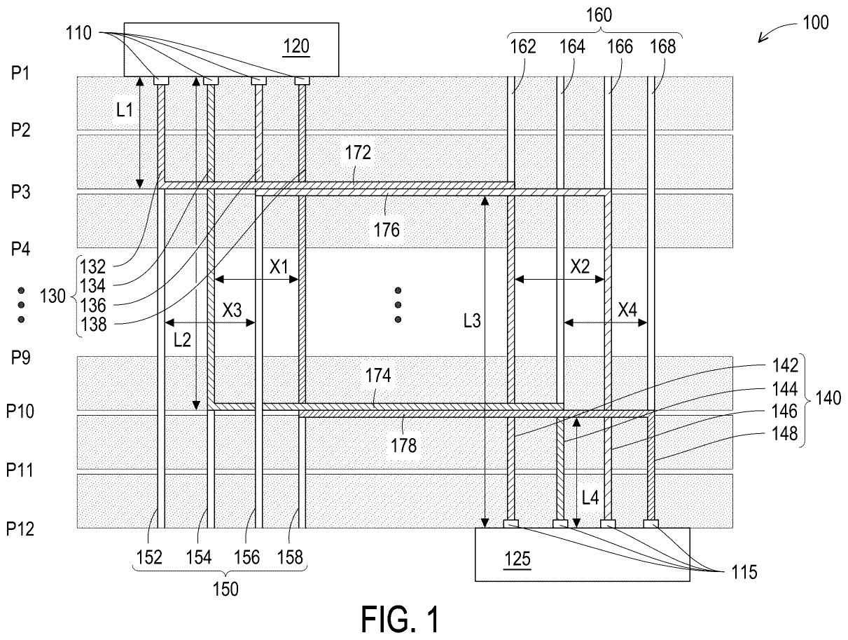

FIG. 1 is a schematic diagram of a circuit board structure according to an embodiment of the present disclosure. It should be noted that in FIG. 1, via hole signal transmission regions 132, 134, 136, 138, 142, 144, 146, and 148 are illustrated with slashes for distinguishing, and non-via hole signal transmission regions 152, 154, 156, 158, 162, 164, 166, and 168 are shown without slashes. In addition, for the simplicity of drawings, circuit layers P1 to P4 and P9 to P12 only show a first pad group 110, a second pad group 115 and traces 172, 174, 176, and 178 connected between a first via hole signal transmission region group 130 and a second via hole signal transmission region group 140.

Please refer to FIG. 1. A circuit board structure 100 of this embodiment includes a plurality of circuit layers P1 to P4 . . . P9 to P12, the first via hole signal transmission region group 130 and the second via hole signal transmission region group 140. The plurality of circuit layers P1 to P4 . . . P9 to P12 are stacked at intervals and separated by an insulating layer. The circuit layers P1 to P4 . . . P9 to P12 in this embodiment are exemplified as twelve layers. The circuit layers between the circuit layers P4 and P9 are omitted. The circuit layers P1 to P4 . . . P9 to P12 are illustrated in sequence of P1 to P4 . . . P9 to P12 from top to bottom. Of course, the number of circuit layers P1 to P4 . . . P9 to P12 is not limited by the disclosure.

The circuit layers P1 to P4 . . . P9 to P12 include the first pad group 110 and the second pad group 115 located on different layers. In this embodiment, the first pad group 110 is located on the uppermost layer, which is the 1^{st} circuit layer P1. The second pad group 115 is located on the lowermost layer, which is the 12^{th} circuit layer P12.

The circuit board structure 100 further includes a first electronic component 120 and a second electronic component 125, which are respectively disposed on the first pad group 110 and the second pad group 115, so that the first electronic component 120 is disposed on the 1^{st} circuit layer P1 and the second electronic component 125 is disposed on the 12^{th} circuit layer P12. The first electronic component 120 is, for example, a processor, and the second electronic component 125 is, for example, a memory. However, the types of the first electronic component 120 and the second electronic component 125 are not limited thereto.

In other embodiments, the first electronic component 120 and the second electronic component 125 may also be embedded inside the circuit board, and the first pad group 110 and the second pad group 115 may also be located on the circuit layer inside the circuit board.

As shown in FIG. 1, a projection of the first pad group 110 on the plane where the second pad group 115 is located is at least partially staggered from the second pad group 115. Therefore, the first pad group 110 is electrically connected to the second pad group 115 through a redistribution circuit. In this embodiment, the redistribution circuit consists of the first via hole signal transmission region group 130, the traces 172, 174, 176, and 178 and the second via hole signal transmission region group 140. Of course, in other embodiments, the projection of the first pad group 110 on the plane where the second pad group 115 is located may also coincide with the second pad group 115.

Specifically, the first via hole signal transmission region group 130 is connected to the first pad group 110 and is conducted to ones (for example, circuit layers P3, P10) of the plurality of circuit layers P1 to P4 . . . P9 to P12. The second via hole signal transmission region group 140 is conducted to the ones (circuit layers P3, P10) of the plurality of circuit layers P1 to P4 . . . P9 to P12, and is conducted to the first via hole signal transmission region group 130, and the second via hole signal transmission region group 140 is connected the second pad group 115. That is to say, the first pad group 110 is conducted to the second pad group 115 through the first via hole signal transmission region group 130, the circuit layers P3 and P10, and the second via hole signal transmission region group 140.

In the first via hole signal transmission region group 130, the two adjacent via hole signal transmission regions 132 and 134 have different lengths, the two adjacent via hole signal transmission regions 134 and 136 have different lengths, and the two adjacent via hole signal transmission regions 136 and 138 have different lengths. In this embodiment, the via hole signal transmission regions 132, 134, 136, and 138 have two lengths L1 and L2, and the via hole signal transmission regions 132 and 136 with the length L1 and the via hole signal transmission regions 134 and 138 with the length L2 are arranged in a staggered manner.

In addition, in the second via hole signal transmission region group 140, the two adjacent via hole signal transmission regions 142 and 144 have different lengths, the two adjacent via hole signal transmission regions 144 and 146 have different lengths, and the two adjacent via hole signal transmission regions 146 and 148 have different lengths. In this embodiment, the via hole signal transmission regions 142, 144, 146, and 148 have two lengths L3 and L4, and the via hole signal transmission regions 142 and 146 with the length L3 and the via hole signal transmission regions 144 and 148 with the length L4 are arranged in a staggered manner.

Through such design, since the two adjacent via hole signal transmission regions 132, 134, 136, and 138 in the first via hole signal transmission region group 130 and the two adjacent via hole signal transmission regions 142, 144, 146, and 148 in the second via hole signal transmission region group 140 have different lengths, it is possible to reduce the probability of mutual coupling as well as the chance of signal interference. Of course, in other embodiments, the via hole signal transmission regions 132, 134, 136, and 138 of the first via hole signal transmission region group 130 or/and the via hole signal transmission regions 142, 144, 146, and 148 of the second via hole signal transmission region group 140 may have more than two types of lengths, the present disclosure is not limited to the drawings.

In terms of a circuit board structure with twelves layers, since the 1st circuit layer P1 and the 12^{th} circuit layer P12 are equipped with more traces, the 2^{nd} circuit layer P2 and the 11^{th} circuit layer P11 may be set as the ground layers. Therefore, the traces 172, 174, 176, and 178 connected to the via hole signal transmission regions 132, 134, 136, and 138 of the first via hole signal transmission region group 130 and the via hole signal transmission regions 142, 144, 146, and 148 of the second via hole signal transmission region group 140 may be disposed on the 3^{rd} circuit layer P3 to the 10^{th} circuit layer P10.

In this embodiment, the traces 172 and 176 connected to the two via hole signal transmission regions 132 and 136 of the first via hole signal transmission region group 130 are disposed on the 3^{rd} circuit layer P3, and the traces 174 and 178 connected to the two via hole signal transmission regions 134 and 138 of the first via hole signal transmission region group 130 are disposed on the 10^{th} circuit layer P10.

Through such design, it is possible for the two via hole signal transmission regions 134 and 138 of the first via hole signal transmission region group 130 to have a greater distance X1 between the 3^{rd} circuit layer P3 and the 10^{th} circuit layer P10, thereby significantly reducing interference. Similarly, it is possible for the two via hole signal transmission regions 142 and 146 of the second via hole signal transmission region group 140 to have a greater distance X2 between the 3^{rd} circuit layer P3 and the 10^{th} circuit layer P10, thereby significantly reducing interference.

In other embodiments, if the plurality of circuit layers have a total of n layers, and n>5, the first via hole signal transmission region group 130 and the second via hole signal transmission region group 140 are conducted to at least two of the 3^{rd} circuit layer to the n-2th circuit layer arranged in sequence from top to bottom in the plurality of circuit layers, and the disclosure is not limited to FIG. 1.

In addition, in this embodiment, the circuit board structure 100 further includes a first non-via hole signal transmission group 150 which corresponds to and is connected to the first via hole signal transmission region group 130. The circuit board structure 100 further includes a second non-via hole signal transmission region group 160, which corresponds to and is connected to the second via hole signal transmission region group 140.

The via hole signal transmission regions 132, 134, 136, and 138 of the first via hole signal transmission region group 130 correspond to and are connected to the non-via hole signal transmission regions 152, 154, 156, and 158 (that is, via stub) of the first non-via hole signal transmission region group 150. The via hole signal transmission regions 132, 134, 136, and 138 and the non-via hole signal transmission regions 152, 154, 156, and 158 may be manufactured together, for example, by mechanical drilling through the circuit board and then plated with copper. The segments connected between the first pad group 110 and the traces 172, 174, 176, and 178 serve as via hole signal transmission regions 132, 134, 136, and 138, which are part of the circuit path, and the remaining segments become the non-via hole signal transmission regions 152, 154, 156, and 158.

In this embodiment, in the first non-via hole signal transmission region group 150, the two adjacent non-via hole signal transmission regions 152 and 154 have different lengths, the two adjacent non-via hole signal transmission regions 154 and 156 have different lengths, and the two adjacent non-via hole signal transmission regions 156 and 158 have different lengths.

Similarly, in the second non-via hole signal transmission region group 160, the two adjacent non-via hole signal transmission regions 162 and 164 have different lengths, the two adjacent non-via hole signal transmission regions 164 and 166 have different lengths, and the two adjacent non-via hole signal transmission regions 166 and 168 have different lengths.

Through such design, it is possible to prevent signal coupling or/and multiple reflections that affect signal performance due to equal lengths and too much proximity of adjacent non-via hole signal transmission regions 152, 154, 156, and 158 in the first non-via hole signal transmission region group 150 as well as equal lengths and too much proximity of adjacent non-via hole signal transmission regions 162, 164, 166, and 168 in the second non-via hole signal transmission region group 160.

In this embodiment, the traces 172 and 176 connected to the two via hole signal transmission regions 132 and 136 of the first via hole signal transmission region group 130 are disposed on the 3^{rd} circuit layer P3, and connected to the two via hole signal transmission regions 142 and 146 of the second via hole signal transmission region group 140. The traces 174 and 178 connected to the two via hole signal transmission regions 134 and 138 of the first via hole signal transmission region group 130 are disposed on the 10^{th} circuit layer P10, and connected to the two via hole signal transmission regions 144 and 148 of the second via hole signal transmission region group 140. Such design allows two adjacent non-via hole signal transmission regions 152 and 156 in the first non-via hole signal transmission region group 150 to have a greater distance X3 between the 3^{rd} circuit layer P3 and the 10^{th} circuit layer P10, thereby significantly reducing interference.

Similarly, the two adjacent non-via hole signal transmission regions 164 and 168 in the second non-via hole signal transmission region group 160 may have a greater distance X4 between the 3^{rd} circuit layer P3 and the 10^{th} circuit layer P10, thereby significantly reducing interference.

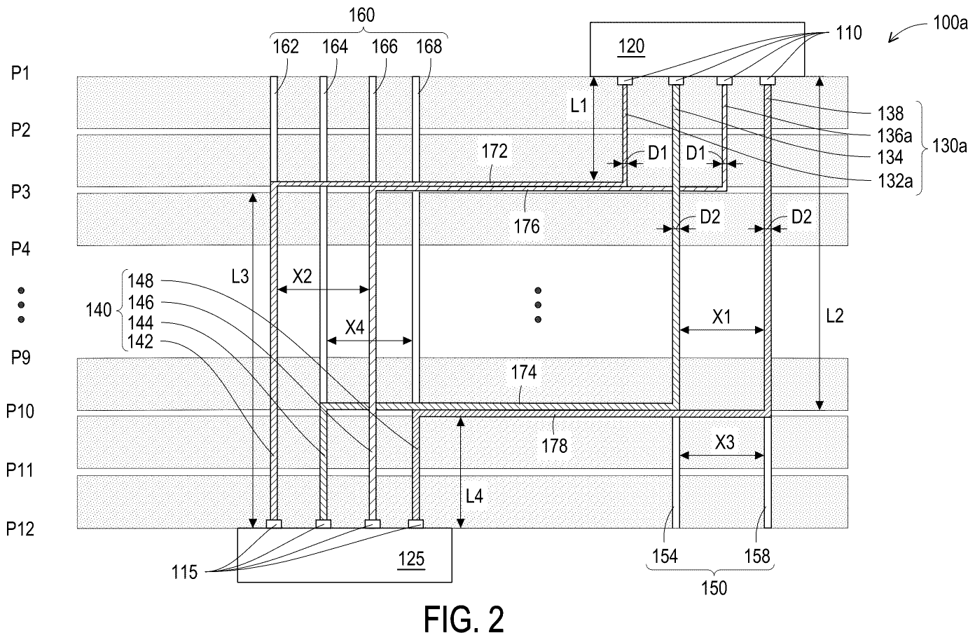

FIG. 2 is a schematic diagram of a circuit board structure according to another embodiment of the present disclosure. Please refer to FIG. 2. The main difference between the circuit board structure 100a of FIG. 2 and the circuit board structure 100 of FIG. 1 is that in the first via hole signal transmission region group 130a of the circuit board structure 100a, the two adjacent via hole signal transmission regions 132a and 134, the two adjacent via hole signal transmission regions 134 and 136a, and the two adjacent via hole signal transmission regions 136a and 138 are different in diameter.

In this embodiment, the via hole signal transmission regions 132a and 136a are, for example, micro vias, which are formed by, for example, laser and then plated with copper. The via hole signal transmission regions 134 and 138 are, for example, PTH vias, which are formed by, for example, mechanical drilling and then plated with copper. The diameter D1 of the micro via is smaller than the diameter D2 of the PTH via. The diameter D1 of the micro via is about 6 mm (that is, 60 microns), and the minimum diameter D2 of PTH vias is about 8 mm (that is, 80 microns).

Therefore, due to the small diameter of the via hole signal transmission regions 132a and 136a in the form of micro via, compared with the via hole signal transmission regions 134 and 138 in the form of PTH vias, at least a width of 1 mm (that is, 10 microns) may be left around the via hole signal transmission regions 132a and 136a in the form of micro via, thereby increasing the distance between the adjacent via hole signal transmission regions 134 and 138 and reducing signal interference.

In addition, compared with PTH via that is formed by penetrating the entire circuit board through mechanical drilling, which results in the formation of the non-via hole signal transmission regions 154 and 158 (via stub), since the via hole signal transmission regions 132a and 136a in the form of micro via are formed by laser, it is only required to form the via hole signal transmission regions with the required depth without forming the non-via hole signal transmission regions. Therefore, the distance X3 between the two adjacent non-via hole signal transmission regions 154 and 158 in the first non-via hole signal transmission region group 150 in FIG. 2 is large enough, even if the two non-via hole signal transmission regions 154 and 158 have the same length, the signal interference between them may be lower.

Of course, in an embodiment not shown, the via hole signal transmission regions of the first via hole signal transmission region group 130 and the via hole signal transmission regions of the second via hole signal transmission region group 140 both may also be in the form of micro via, so that there is a large distance between them and the signal performance may be improved.

Based on the above, the circuit board structure of the present disclosure allows the first pad group and the second pad group to be electrically connected through the first via hole signal transmission region group and the second via hole signal transmission region group. Two adjacent via hole signal transmission regions in the first via hole signal transmission region group have different lengths, and two adjacent via hole signal transmission regions in the second via hole signal transmission region group have different lengths. Such design makes it possible to reduce the probability that two adjacent via hole signal transmission regions in the first via hole signal transmission region group and the second via hole signal transmission region group are coupled to each other, thereby reducing crosstalk and improving signal performance.

What is claimed is:

1. A circuit board structure, comprising:
a plurality of circuit layers stacked at intervals and comprising a first pad group and a second pad group located on different layers;
a first via hole signal transmission region group connected to the first pad group and conducted to ones of the plurality of circuit layers, wherein two adjacent via hole signal transmission regions in the first via hole signal transmission region group have different lengths; and
a second via hole signal transmission region group conducted to the ones of the plurality of circuit layers and conducted to the first via hole signal transmission region group, wherein the second via hole signal transmission region group is connected to the second pad group, and two adjacent via hole signal transmission regions in the second via hole signal transmission region group have different lengths.

2. The circuit board structure according to claim 1, further comprising:
a first non-via hole signal transmission region group corresponding to and connected to the first via hole signal transmission region group, wherein two adjacent non-via hole signal transmission regions in the first non-via hole signal transmission region group have different lengths.

3. The circuit board structure according to claim 1, further comprising:
a second non-via hole signal transmission region group corresponding to and connected to the second via hole signal transmission region group, wherein two adjacent non-via hole signal transmission regions in the second non-via hole signal transmission region group have different lengths.

4. The circuit board structure according claim 1, wherein in the first via hole signal transmission region group or/and the second via hole signal transmission region group, the two adjacent via hole signal transmission regions are different in diameter.

5. The circuit board structure according to claim 4, wherein one of the two adjacent via hole signal transmission regions is a micro via.

6. The circuit board structure according to claim 5, wherein the other of the two adjacent via hole signal transmission regions is a PTH via, and a diameter of the micro via is smaller than a diameter of the PTH via.

7. The circuit board structure according to claim 1, wherein each of the first via hole signal transmission region group and the second via hole signal transmission region group comprises a plurality of via hole signal transmission regions, the plurality of via hole signal transmission regions have two types of lengths, and the plurality of via hole signal transmission regions having the two types of lengths are disposed in a staggered manner.

8. The circuit board structure according to claim 1, wherein the first pad group is located on an uppermost layer, and the second pad group is located on a lowermost layer.

9. The circuit board structure according to claim 8, wherein the plurality of circuit layers having a total of n layers are disposed in sequence from top to bottom, and n>5, the first via hole signal transmission region group and the second via hole signal transmission region group are conducted to at least two of a 3^{rd} circuit layer to an n-2th circuit layer in the plurality of circuit layers.

10. The circuit board structure according to claim 1, further comprising a first electronic component and a second electronic component respectively disposed in the first pad group and the second pad group.
